(19) United States
(12) Patent Application Publication
(10) Pub. No.: US 2026/0227427 A1
(43) Pub. Date: Aug. 6, 2026

(54) APPARATUS FOR HARDWARE TESTING USING A PLUGGABLE ELECTRONIC DEVICE

(71) Applicant: Aivres Systems Inc., Fremont, CA (US)

(72) Inventor: Wei Chang CHEN, Taipei City (TW)

(21) Appl. No.: 19/635,336

(22) Filed: Mar. 31, 2026

(51) Int. Cl. G01R 1/04

(52) U.S. Cl. CPC G01R 1/0416

(57) ABSTRACT

A test adapter apparatus for repeated functional testing of a pluggable electronic device includes a first connector for mating with a device under test, a second connector for mating with the pluggable electronic device, and an electrical interconnection path establishing an electrical pass-through path therebetween. Logic circuitry detects a signal associated with a test event and accumulates a usage count of the test adapter apparatus. A non-volatile memory persistently stores a cumulative usage count. The logic circuitry determines whether the cumulative usage count satisfies a predetermined wear threshold and, in response, alters at least one electrical interface-detection signal of the test adapter apparatus to indicate invalidation for further testing. In some embodiments, the logic circuitry provides a visual warning, applies signal conditioning to the detected signal, and is implemented using a CPLD.

### TECHNICAL FIELD

The present disclosure relates to electronic test systems and interposer devices, and more particularly to a wear-managed test adapter for repeated mating between a device under test and a pluggable electronic device.

### BACKGROUND

In manufacturing, qualification, repair, and diagnostic environments, functional testing is often performed by repeatedly connecting a pluggable electronic device to a corresponding interface of a device under test. Representative examples include testing storage drives with storage backplanes, testing PCIe add-in cards with server-side PCIe receptacles, testing riser cards with motherboards or expansion slots, and testing memory modules with memory expansion slots.

Such repeated testing can subject connectors in the test setup to substantial mechanical wear resulting from repeated insertion and removal cycles. Over time, connector wear may degrade electrical contact quality, introduce intermittent failures, and reduce test reliability. In some cases, a reference pluggable electronic device, such as a device previously verified to be operational, may be used repeatedly across multiple devices under test and may itself suffer connector damage, thereby shortening the useful life of the test hardware and increasing cost.

Moreover, absent tracking of cumulative wear experienced during repeated test cycles, an overused reference device may continue to be employed after its connector life has been substantially exhausted, potentially leading to inaccurate test outcomes or damage to associated hardware. There is therefore a need for a mechanism that can automatically invalidate a worn fixture or otherwise signal that the fixture should no longer be used.

Accordingly, a need exists for a test adapter apparatus that can be interposed between a device under test and a pluggable electronic device, that can monitor usage during repeated functional testing, and that can invalidate itself for further testing after a predetermined wear threshold has been reached.

### SUMMARY

A system of one or more computers can be configured to perform particular operations or actions by virtue of having software, firmware, hardware, or a combination thereof installed on the system that, in operation, causes the system to perform the actions. One or more computer programs can be configured to perform particular operations or actions by virtue of including instructions that, when executed by data processing apparatus, cause the apparatus to perform the actions.

In one general aspect, a test adapter apparatus may include a first connector configured to removably mate with a corresponding interface of the device under test. The test adapter apparatus may also include a second connector configured to removably mate with the pluggable electronic device.

The test adapter apparatus may further include an electrical interconnection path between the first connector and the second connector to establish an electrical pass-through path between the device under test and the pluggable electronic device. The test adapter apparatus may additionally include logic circuitry configured to detect a signal associated with a test event and determine a cumulative usage count of the test adapter apparatus based on the detected signal.

The test adapter apparatus may further include a non-volatile memory in communication with the logic circuitry, the non-volatile memory configured to persistently store the cumulative usage count. The test adapter apparatus may also include the logic circuitry further configured to determine that the cumulative usage count satisfies a predetermined wear threshold and, in response, alter at least one electrical interface-detection signal of the test adapter apparatus to indicate invalidation of the test adapter apparatus for further testing.

Other embodiments of this aspect include corresponding computer systems, apparatus, and computer programs recorded on one or more computer storage devices, each configured to perform the actions of the methods.

Implementations may include one or more of the following features. The test adapter apparatus may be configured such that altering the at least one electrical interface-detection signal includes pulling down, interrupting, or forcing a state of a presence pin or a readiness pin of the first connector to simulate an absent or unready condition of the device under test. The test adapter apparatus may be configured such that altering the at least one electrical interface-detection signal includes pulling down, interrupting, or forcing a state of a presence pin or a readiness pin of the second connector to simulate an absent or unready condition of the pluggable electronic device.

The logic circuitry may be further configured to provide, via a display or an LED, a visual warning indicating that the predetermined wear threshold has been satisfied. The logic circuitry may include signal conditioning logic configured to apply a debounce filter or a defined time window to the detected signal, such that a plurality of signal fluctuations occurring during the test event are interpreted as a single valid cycle for the cumulative usage count.

The detected signal associated with the test event may include an active signal, a reset signal, a presence signal, a clock request signal, a link-up indication, or a link training state transition. The logic circuitry may include a Complex Programmable Logic Device (CPLD), and the non-volatile memory may be in communication with the CPLD.

The non-volatile memory may include a flash memory, and the flash memory may communicate with the logic circuitry over an I2C interface. The logic circuitry may be configured to retrieve the cumulative usage count from the non-volatile memory upon power-up and store an updated cumulative usage count in the non-volatile memory after detection of the test event.

The device under test may include a storage backplane, and the pluggable electronic device may include a storage drive. The first connector may include a male connector configured to mate with the storage backplane, the second connector may include a female connector configured to receive a solid-state drive (SSD), and the signal associated with the test event may include a drive active LED signal.

The device under test may include a server-side Peripheral Component Interconnect Express (PCIe) receptacle, and the pluggable electronic device may include a PCIe add-in card. The pluggable electronic device may include a riser card, and the first connector may be configured to mate with a motherboard or an expansion slot of the device under test.

The device under test may include a memory expansion slot, and the pluggable electronic device may include a Dual In-line Memory Module (DIMM) or a Compute Express Link (CXL) memory module. The pluggable electronic device may include a reference device previously verified to be operational, and the test adapter apparatus may be configured as a sacrificial wear component to protect a connector of the reference device from mechanical wear during repeated mating cycles with successive devices under test.

Implementations of the described techniques may include hardware, a method or process, or a computer tangible medium.

In one general aspect, a method may include establishing an electrical pass-through path between the device under test and the pluggable electronic device using an electrical interconnection path between a first connector removably mated with a corresponding interface of the device under test and a second connector removably mated with the pluggable electronic device. The method may also include detecting, by logic circuitry, a signal associated with a test event.

The method may further include determining, by the logic circuitry, a cumulative usage count of the test adapter apparatus based on the detected signal. The method may additionally include persistently storing the cumulative usage count in a non-volatile memory in communication with the logic circuitry.

The method may further include determining, by the logic circuitry, that the cumulative usage count satisfies a predetermined wear threshold and, in response, altering at least one electrical interface-detection signal of the test adapter apparatus to indicate invalidation of the test adapter apparatus for further testing.

Other embodiments of this aspect include corresponding computer systems, apparatus, and computer programs recorded on one or more computer storage devices, each configured to perform the actions of the methods.

Implementations may include one or more of the following features. Altering the at least one electrical interface-detection signal may include pulling down, interrupting, or forcing a state of a presence pin or a readiness pin of the first connector to simulate an absent or unready condition to the device under test or the pluggable electronic device.

The method may include applying, by signal conditioning logic of the logic circuitry, a debounce filter or a defined time window to the detected signal, such that a plurality of signal fluctuations occurring during the test event are interpreted as a single valid cycle for the cumulative usage count.

Implementations of the described techniques may include hardware, a method or process, or a computer tangible medium.

In one general aspect, a test system may include a device under test having an interface. The test system may also include a pluggable electronic device.

The test system may further include a test adapter apparatus having a first connector removably mated with the interface of the device under test, a second connector removably mated with the pluggable electronic device, and an electrical interconnection path between the first connector and the second connector to establish an electrical pass-through path between the device under test and the pluggable electronic device.

The test system may further include logic circuitry configured to detect a signal associated with a test event and determine a cumulative usage count of the test adapter apparatus based on the detected signal, and a non-volatile memory in communication with the logic circuitry, the non-volatile memory configured to persistently store the cumulative usage count.

The test system may further include the logic circuitry configured to determine that the cumulative usage count satisfies a predetermined wear threshold and, in response, alter at least one electrical interface-detection signal of the test adapter apparatus to indicate invalidation of the test adapter apparatus for further testing.

Other embodiments of this aspect include corresponding computer systems, apparatus, and computer programs recorded on one or more computer storage devices, each configured to perform the actions of the methods.

Implementations may include one or more of the following features. Altering the at least one electrical interface-detection signal may include pulling down, interrupting, or forcing a state of a presence pin or a readiness pin of the first connector to simulate an absent or unready condition to the device under test or the pluggable electronic device.

Implementations of the described techniques may include hardware, a method or process, or a computer tangible medium.

### BRIEF DESCRIPTION OF THE DRAWINGS

Certain features of various embodiments of the present technology are set forth with particularity in the appended claims. A better understanding of the features and advantages of the technology will be obtained by reference to the following detailed description that sets forth illustrative embodiments, in which the principles of the disclosure are utilized, and the accompanying drawings of which:

FIG. 1 shows a view of an example hardware testing environment involving a storage backplane and a solid-state drive (SSD), illustrating the repetitive mechanical mating cycles in a hardware testing system.

FIG. 2 is an example block diagram of a test system with a device under test, a pluggable electronic device, and a test adapter apparatus, in accordance with some embodiments.

FIG. 3 is an example hardware and logic block diagram of the test adapter apparatus of FIG. 2, illustrating the internal electrical pass-through path, logic circuitry, memory, and lockout mechanisms, in accordance with some embodiments.

FIG. 4A is a schematic block diagram illustrating an embodiment of the test adapter apparatus configured with SFF-8639 connectors for testing a solid-state drive with a storage backplane, in accordance with some embodiments.

FIG. 4B is a logical state diagram illustrating the data flow and operation between a Complex Programmable Logic Device (CPLD), an EEPROM, and a display of the test adapter apparatus during a test cycle, in accordance with some embodiments.

FIG. 4C is a plan view illustrating the physical form factor of the test adapter apparatus of FIG. 4A interposed between a storage backplane and a solid-state drive, in accordance with some embodiments.

FIG. 4D is an exploded perspective view illustrating the mechanical assembly of the test adapter apparatus mating a solid-state drive to a storage carrier tray, in accordance with some embodiments.

FIG. 4E is a schematic plan view illustrating an embodiment of the test adapter apparatus configured for testing a Peripheral Component Interconnect Express (PCIe) card with a motherboard, in accordance with some embodiments.

FIG. 4F is a schematic plan view illustrating another embodiment of the test adapter apparatus configured for testing a riser card with an expansion slot of a device under test, in accordance with some embodiments.

FIG. 4G is a perspective view illustrating yet another embodiment of the test adapter apparatus configured for testing a Dual In-line Memory Module (DIMM) or a Compute Express Link (CXL) module with a memory expansion slot, in accordance with some embodiments.

FIG. 5 is a flowchart illustrating a method for managing the functional lifespan of a test adapter apparatus during repetitive functional testing, in accordance with some embodiments.

### DETAILED DESCRIPTION OF EMBODIMENTS

In the following description, certain specific details are set forth in order to provide a thorough understanding of various embodiments of the disclosure. However, one skilled in the art will understand that the disclosure may be practiced without these details. Moreover, while various embodiments of the disclosure are disclosed herein, many adaptations and modifications may be made within the scope of the disclosure in accordance with the common general knowledge of those skilled in this art. Such modifications include the substitution of known equivalents for any aspect of the disclosure in order to achieve the same result in substantially the same way.

Unless the context requires otherwise, throughout the present specification and claims, the word “comprise” and variations thereof, such as, “comprises” and “comprising” are to be construed in an open, inclusive sense, that is as “including, but not limited to.” Recitation of numeric ranges of values throughout the specification is intended to serve as a shorthand notation of referring individually to each separate value falling within the range inclusive of the values defining the range, and each separate value is incorporated in the specification as it were individually recited herein. Additionally, the singular forms “a,” “an” and “the” include plural referents unless the context clearly dictates otherwise.

Reference throughout this specification to “one embodiment” or “an embodiment” means that a particular feature, structure or characteristic described in connection with the embodiment is included in at least one embodiment of the present disclosure. Thus, the appearances of the phrases “in one embodiment” or “in an embodiment” in various places throughout this specification are not necessarily all referring to the same embodiment, but may be in some instances. Furthermore, the particular features, structures, or characteristics may be combined in any suitable manner in one or more embodiments.

The present disclosure will be described primarily in the context of a storage-interface testing environment because that environment provides a practical example of repeated mating and unmating of a portable test device with a device under test. This example should not be understood as limiting. As discussed further below, the same principles may be applied to other pluggable-device testing scenarios, including testing of PCIe add-in cards, riser cards, and memory modules.

In the illustrated storage example, the objective of the test process is not necessarily to qualify the storage media of the portable device itself, but rather to verify that the interface path associated with the device under test is functioning properly. In server architectures, storage backplanes commonly provide multiple drive-bay connections, and the drives in those bays communicate with the system board and/or a controller through the backplane and associated connectors or cables. Vendor documentation likewise describes drive backplanes as supporting multiple storage devices and providing the connection path to the system board or RAID/controller circuitry.

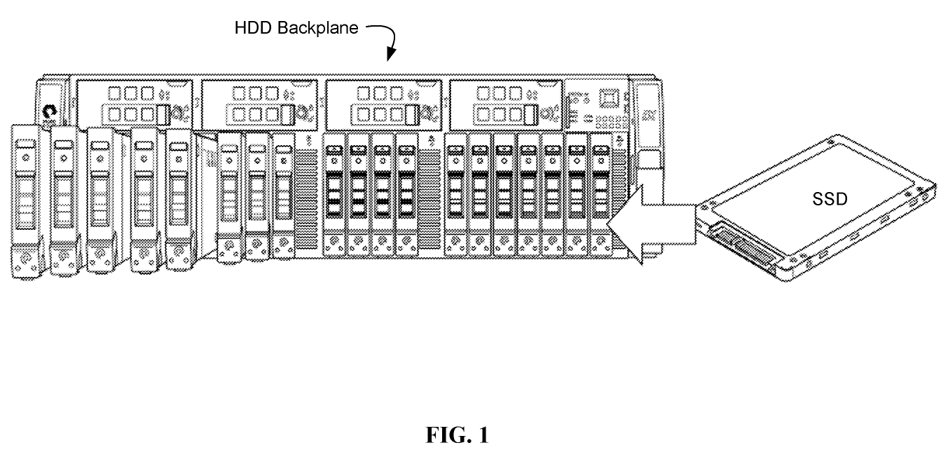

FIG. 1 shows an example hardware testing environment involving a hard disk drive (HDD) backplane and a solid-state drive (SSD). In some implementations, the HDD backplane is mounted in, or otherwise electrically coupled to, a server platform or motherboard and provides a plurality of drive slots, each slot having a corresponding interface configured to receive a storage device. FIG. 1 illustrates a practical pre-shipment or factory verification environment in which a previously verified SSD is repeatedly inserted into and removed from one or more corresponding interfaces of the HDD backplane in order to verify proper operation of the HDD slots and associated interface paths.

More specifically, in one practical workflow, a system assembled with the HDD backplane is brought to a function-verification station before shipment. A portable SSD serving as a reference device previously verified to be operational may be inserted into a selected slot of the HDD backplane so that the host system can detect and communicate with the reference device through the relevant PCIe, SAS, SATA, or similar storage path. The host can then execute one or more preconfigured verification operations directed to the slot and interface under test. By way of example, the host may perform device-detection operations, link verification, command issuance, read operations, write operations, and/or read-back operations to determine whether the HDD slot, associated connector, and corresponding interface path are functioning properly.

Stated differently, the SSD is used as a known operational endpoint for exercising the electrical and protocol path associated with the HDD slot under test, rather than as the object of the test itself. In that sense, the test can validate the slot connector, the HDD backplane routing, associated sideband or status signaling, and the communication path to the system board, storage controller, or other host-side circuitry. Where the HDD backplane has multiple drive bays, the same reference SSD may be inserted sequentially into different slots so that each corresponding slot and interface path can be verified. In some implementations involving trays, cages, or RAID-related configurations, the reference SSD may be used in connection with one or more selected slots to verify recognition, communication, and read/write behavior of the relevant HDD-side configuration.

During such verification, the system may collect performance or correctness information associated with the HDD slot and interface under test. For instance, verification software may determine whether the reference SSD is properly detected at a given slot, whether commands issued through that slot complete successfully, whether data written through the relevant interface path can be read back correctly, whether error conditions are reported, and, in some implementations, whether throughput or response behavior falls within an expected range. The particular verification routine can vary by platform and storage protocol, but in a production environment the same reference SSD may be repeatedly inserted into successive slots of a given HDD backplane and/or into corresponding slots of successive systems.

Repetition of that process can create substantial mechanical wear. In particular, each test cycle may involve insertion and removal of the SSD relative to a corresponding connector of the HDD backplane. Over many cycles, that repeated mating can damage or degrade one or both mating connectors, including the connector associated with the reference SSD and the corresponding connector of the HDD backplane. Such degradation may increase replacement frequency for the reference SSD, increase testing cost, and adversely affect the reliability of subsequent verification. In this respect, FIG. 1 illustrates a practical testing scenario in which a portable reference device is repeatedly used to verify HDD slots and interface paths, while the repeated mating cycles are concentrated at the device-side and backplane-side connectors.

Although FIG. 1 illustrates an HDD backplane and SSD, similar repeated test conditions can arise in other hardware-verification scenarios in which a pluggable electronic device is used as a portable reference article. Examples include repeated insertion of a PCIe add-in card into a server-side PCIe receptacle, repeated insertion of a riser card into a motherboard or expansion slot, and repeated insertion of a DIMM or CXL memory module into a memory expansion slot. In each case, a portable device may be used across multiple units under test or multiple interfaces of a given unit, and repeated mating cycles can accumulate wear at the relevant connectors.

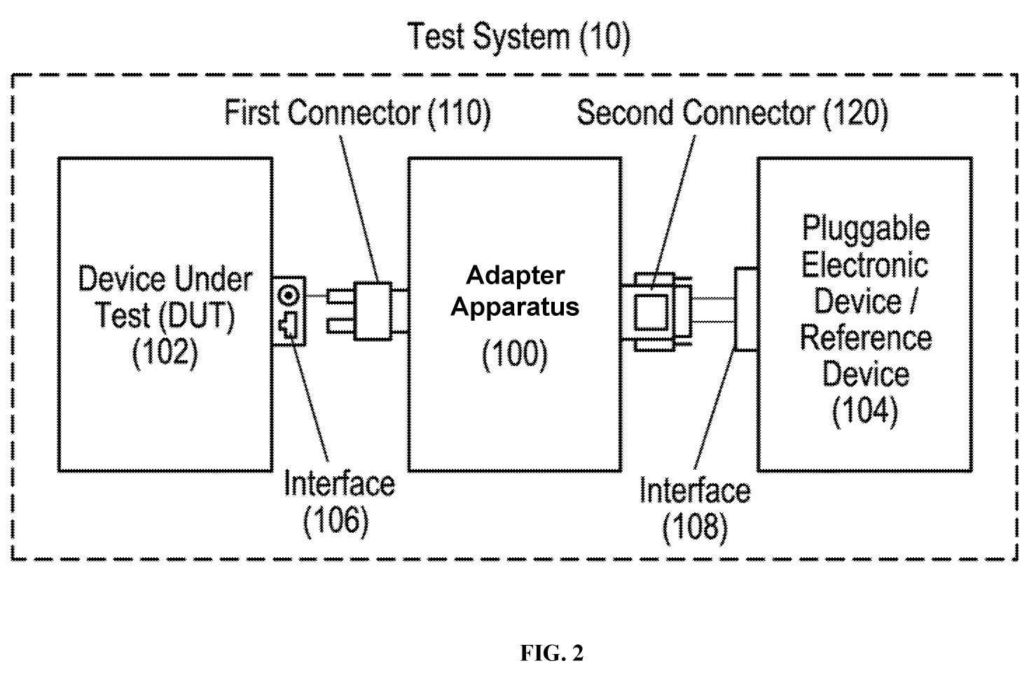

FIG. 2 is an example block diagram of a test system 10, in accordance with some embodiments. As shown, the test system 10 includes a device under test (DUT) 102, a pluggable electronic device / reference device 104, and an adapter apparatus 100 disposed between the device under test 102 and the pluggable electronic device / reference device 104. The adapter apparatus 100 is configured to be interposed between the device under test 102 and the pluggable electronic device / reference device 104 during repeated functional testing.

In the illustrated embodiment, the device under test 102 includes an interface 106, and the pluggable electronic device / reference device 104 includes an interface 108. The adapter apparatus 100 includes a first connector 110 configured to removably mate with the interface 106 of the device under test 102, and a second connector 120 configured to removably mate with the interface 108 of the pluggable electronic device / reference device 104. In this manner, the adapter apparatus 100 is mechanically coupled between the device under test 102 and the pluggable electronic device / reference device 104 such that repeated mating and unmating occurs through the first connector 110 and the second connector 120 of the adapter apparatus 100. In some embodiments, the second connector 120 includes an interface identical/similar to the interface 106 of the device under test. The first connector 110 includes an interface identical/similar to the interface 108 of the pluggable electronic device 104.

The adapter apparatus 100 further includes (additional details are shown in later figures) an electrical interconnection path extending between the first connector 110 and the second connector 120 so as to establish an electrical pass-through path between the device under test 102 and the pluggable electronic device / reference device 104. Accordingly, when the first connector 110 is mated with the interface 106 and the second connector 120 is mated with the interface 108, signals may pass through the adapter apparatus 100 to permit the device under test 102 to communicate with the pluggable electronic device / reference device 104 for purposes of functional verification. Depending on the implementation, the electrical pass-through path may carry data signals, control signals, sideband signals, power, ground, or combinations thereof.

In some embodiments, the pluggable electronic device / reference device 104 is a reference device previously verified to be operational. In such embodiments, the pluggable electronic device / reference device 104 may serve as a known operational endpoint for exercising and verifying the interface path associated with the device under test 102, while the adapter apparatus 100 functions as an intermediate test fixture. For example, the pluggable electronic device / reference device 104 may be repeatedly used with successive devices under test 102 or repeatedly connected to and disconnected from a given device under test 102, during production, qualification, repair, or diagnostic testing.

The adapter apparatus 100 may further include logic circuitry (additional details are shown in later figures) configured to detect a signal associated with a test event and determine a cumulative usage count of the adapter apparatus 100 based on the detected signal. In some implementations, the signal associated with the test event may correspond to a device activity signal, a reset signal, a presence signal, a clock request signal, a link-up indication, a link training state transition, or another signal indicative of successful participation of the adapter apparatus 100 in a test cycle. The logic circuitry may increment or otherwise update the cumulative usage count in response to occurrence of the test event.

In some storage-related implementations, the signal associated with the test event may be derived from an activity-indicator signal of a pluggable storage device, such as a drive active LED signal. The logic circuitry, which may include a CPLD or other suitable logic device, may monitor the signal and apply signal qualification, such as debounce filtering or time-window-based evaluation, so that repeated pulses, flicker, or burst activity associated with a single test cycle are treated as one valid usage event for purposes of the cumulative usage count. The cumulative usage count may be stored in a non-volatile memory, such as an EEPROM, for retention across power cycles, and may be written or retrieved over an I2C interface or other communication bus. In some implementations, the adapter apparatus 100 may further include a local visual indicator, such as a seven-segment display, configured to display the cumulative usage count or other usage-related information.

In some embodiments, the adapter apparatus 100 further includes a non-volatile memory in communication with the logic circuitry. The non-volatile memory is configured to persistently store the cumulative usage count, thereby permitting retention of usage information across power cycles or across successive test operations. In some examples, the logic circuitry may retrieve the cumulative usage count from the non-volatile memory upon power-up and store an updated cumulative usage count in the non-volatile memory after detection of a test event.

In some embodiments, the logic circuitry may further be configured to determine whether the cumulative usage count satisfies a predetermined wear threshold. The predetermined wear threshold may correspond to an expected service life of one or more portions of the adapter apparatus 100, such as the first connector 110, the second connector 120, or both. When the cumulative usage count satisfies the predetermined wear threshold, the logic circuitry may, in response, alter at least one electrical interface-detection signal of the adapter apparatus 100 to indicate invalidation of the adapter apparatus 100 for further testing. By way of example, the logic circuitry may pull down, interrupt, or otherwise force a state of a presence pin or a readiness pin associated with the first connector 110, the second connector 120, or both, such that the device under test 102 and/or the pluggable electronic device / reference device 104 perceives an absent or unready condition.

In some embodiments, the adapter apparatus 100 may additionally provide a local visual indication that the predetermined wear threshold has been satisfied. For example, a display or LED may be controlled by the logic circuitry to output a warning indicating that the adapter apparatus 100 has reached an end-of-life condition or should be removed from further use. Such a visual indication may supplement, rather than replace, the alteration of the electrical interface-detection signal.

In the configuration of FIG. 2, the adapter apparatus 100 may therefore function as a sacrificial wear component positioned between the device under test 102 and the pluggable electronic device / reference device 104. As a result, repeated mechanical insertion and removal can be concentrated at the first connector 110 of the adapter apparatus 100, rather than at a connector of the pluggable electronic device / reference device 104 itself. This arrangement can protect a connector of the reference device from mechanical wear during repeated mating cycles with successive devices under test.

The arrangement of FIG. 2 can provide several technical improvements. By interposing the adapter apparatus 100 between the device under test 102 and the pluggable electronic device / reference device 104, connector wear can be shifted to a replaceable fixture rather than to the reference device itself. By determining and persistently storing the cumulative usage count, the adapter apparatus 100 can track fixture life across repeated test cycles. By invalidating the adapter apparatus 100 when the predetermined wear threshold has been satisfied, the test system 10 can reduce continued use of an over-worn fixture, thereby improving test consistency, reducing connector-related false failures or intermittent behavior, and lowering replacement cost for the pluggable electronic device (reference device) 104.

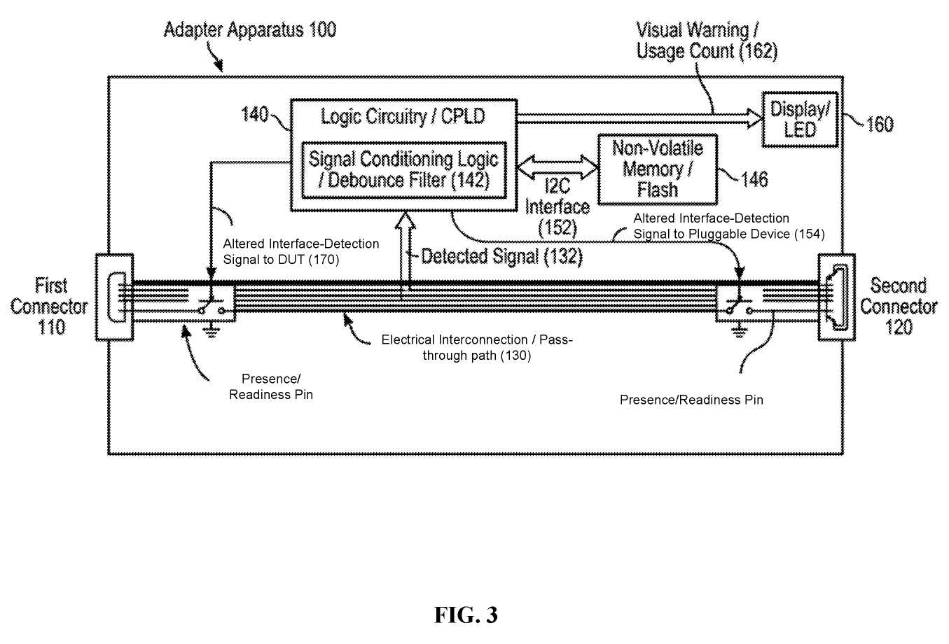

FIG. 3 is an example hardware and logic block diagram of the adapter apparatus 100 of FIG. 2, illustrating an example internal architecture of the adapter apparatus 100, including a first connector 110, a second connector 120, an electrical interconnection (pass-through path) 130, logic circuitry (e.g., CPLD) 140, non-volatile memory (e.g., flash or EEPROM) 146, an I2C interface 152, and a display / LED 160, in accordance with some embodiments.

As shown in FIG. 3, the adapter apparatus 100 includes the first connector 110 and the second connector 120 arranged on opposite sides of the adapter apparatus 100. The first connector 110 is configured to removably mate with a corresponding interface of a device under test (DUT), and the second connector 120 is configured to removably mate with a corresponding interface of a pluggable electronic device. In operation, the adapter apparatus 100 is physically interposed between the DUT and the pluggable electronic device such that repeated insertion and removal occurs at the first connector 110 and the second connector 120 of the adapter apparatus 100.

The first connector 110 and the second connector 120 are electrically coupled by the electrical interconnection 130. In the illustrated embodiment, the electrical interconnection 130 extends through the adapter apparatus 100 to establish an electrical pass-through path between the DUT-side interface and the pluggable-device-side interface. The electrical interconnection 130 may include conductive traces, pads, vias, planes, edge-connector routing, cable terminations, or other conductive structures suitable for carrying signals through the adapter apparatus 100. Depending on the implementation, the electrical interconnection 130 may carry data signals, control signals, sideband signals, clock-related signals, power, ground, or combinations thereof.

In some embodiments, the electrical interconnection 130 is configured to pass one or more signals associated with a test event. As shown in FIG. 3, a detected signal 132 may be tapped, mirrored, sensed, or otherwise obtained from the electrical interconnection 130 and provided to the logic circuitry 140. The detected signal 132 may correspond to a signal indicative of occurrence of a test event or valid participation of the adapter apparatus 100 in a test cycle. By way of example, the detected signal 132 may comprise an active signal, a reset signal, a presence signal, a clock request signal, a link-up indication, a link training state transition, or another signal associated with completion or occurrence of a test event. In a storage implementation, the detected signal 132 may be derived from a drive active LED signal. In other implementations, the detected signal 132 may be derived from protocol-specific sideband or status signaling.

The logic circuitry 140 is configured to detect the detected signal 132 and determine a cumulative usage count of the adapter apparatus 100 based on the detected signal 132. In the illustrated embodiment, the logic circuitry 140 includes signal conditioning logic (such as a debounce filter) 142. The signal conditioning logic 142 may apply a debounce filter, timing qualification, edge qualification, pulse-width qualification, hysteresis-based processing, a defined time window, or another conditioning operation so that a plurality of signal fluctuations associated with a single test event are interpreted as a single valid cycle for purposes of the cumulative usage count. This can be useful where the detected signal 132 exhibits flicker, chatter, repeated transitions, burst activity, or other non-ideal behavior during a test event.

Although FIG. 3 labels the logic circuitry 140 as a complex programmable logic device (CPLD), the logic circuitry is not limited to a CPLD implementation. In some embodiments, the logic circuitry 140 may be implemented using a field-programmable gate array, a microcontroller, an application-specific integrated circuit, discrete logic, or combinations thereof. A CPLD implementation may nevertheless be advantageous in some embodiments because it can provide deterministic signal monitoring, threshold comparison, and lockout control with relatively compact hardware implementation.

The logic circuitry 140 is further in communication with the non-volatile memory 146. In the illustrated embodiment, communication is provided through the I2C interface 152. The non-volatile memory 146 is configured to persistently store the cumulative usage count so that the usage count is retained across power cycles, test-station resets, or disconnection and reconnection of the adapter apparatus 100. In some embodiments, the logic circuitry 140 retrieves the cumulative usage count from the non-volatile memory 146 upon power-up or initialization, updates the cumulative usage count after detection of a valid test event, and writes the updated cumulative usage count back to the non-volatile memory 146.

Although FIG. 3 illustrates the I2C interface 152 and the non-volatile memory 146, other communication interfaces and memory types may be used. For example, the non-volatile memory may comprise flash memory, EEPROM, FRAM, MRAM, or another persistent storage device. Likewise, communication between the logic circuitry 140 and the non-volatile memory may be implemented using I2C, SPI, SMBus, a parallel bus, a serial peripheral interface, or another suitable communication protocol or interconnect.

The logic circuitry 140 is further configured to compare the cumulative usage count to a predetermined wear threshold. The predetermined wear threshold may correspond to an expected service life, insertion-cycle limit, qualification threshold, or replacement threshold associated with one or both of the first connector 110 and the second connector 120. When the cumulative usage count satisfies the predetermined wear threshold, the logic circuitry 140 invalidates the adapter apparatus 100 for further testing by altering at least one electrical interface-detection signal of the adapter apparatus 100.

In the illustrated embodiment, FIG. 3 shows an altered interface-detection signal to DUT 170 and an altered interface-detection signal to pluggable device 154. These signals may be generated or controlled by the logic circuitry 140 to affect a presence / readiness pin associated with the first connector 110, the second connector 120, or both. In some embodiments, invalidation of the adapter apparatus 100 is accomplished by pulling down, interrupting, opening, overriding, or otherwise forcing a state of a presence / readiness pin associated with the first connector 110 so as to simulate an absent or unready condition from the perspective of the DUT. In some embodiments, invalidation of the adapter apparatus 100 is accomplished by pulling down, interrupting, opening, overriding, or otherwise forcing a state of a presence / readiness pin associated with the second connector 120 so as to simulate an absent or unready condition from the perspective of the pluggable electronic device (i.e., the reference device). In still other embodiments, both sides are altered, such that both the DUT side and the pluggable-device side are caused to perceive an absent or unready condition.

In some embodiments, the lockout mechanism of the adapter apparatus 100 need not require disabling both sides of the adapter apparatus 100 in every implementation. In some embodiments, alteration of a single electrical interface-detection signal on only the DUT side may be sufficient to prevent further testing. In some embodiments, alteration of a single electrical interface-detection signal on only the pluggable-device side may be sufficient. In some embodiments, both sides may be altered for redundancy, stronger lockout behavior, or compatibility with different interface standards. The particular presence / readiness pin or other interface-detection signal selected for alteration may vary depending on connector type, interface standard, or system architecture.

As further shown in FIG. 3, the logic circuitry 140 may control the display / LED 160 to provide a visual warning or usage count 162. In some embodiments, the display / LED 160 may present the cumulative usage count, a remaining-life value, a threshold-reached indication, a fault state, or another local status output. In some embodiments, when the cumulative usage count satisfies the predetermined wear threshold, the logic circuitry 140 may cause the display / LED 160 to provide a visual warning indicating that the adapter apparatus 100 has been invalidated for further testing. The visual warning may be implemented by illumination, blinking, color change, numerical display, alphanumeric display, segment-based display output, or another user-perceptible indication.

In some implementations, the visual warning or usage count 162 can facilitate fixture management by allowing an operator to identify whether the adapter apparatus 100 remains usable, is approaching end of life, or has already reached the predetermined wear threshold. In this manner, the display / LED 160 may supplement the electrical lockout function by providing local human-readable status information, while the altered interface-detection signal provides machine-enforced invalidation.

The arrangement shown in FIG. 3 provides several technical effects. By routing repeated mechanical mating cycles through the first connector 110 and the second connector 120 of the adapter apparatus 100, the adapter apparatus 100 can function as a sacrificial wear component that protects a connector of a pluggable electronic device, such as a reference device previously verified to be operational, from mechanical wear during repeated mating cycles. By using the detected signal 132, the signal conditioning logic / debounce filter 142, and the logic circuitry 140 to determine the cumulative usage count, the adapter apparatus 100 can more reliably track actual fixture usage in repeated testing environments. By persistently storing the cumulative usage count in the non-volatile memory 146, the adapter apparatus 100 can preserve life-consumption information across power interruptions and repeated deployments. By altering the interface-detection signal to DUT 170, the altered interface-detection signal to pluggable device 154, or both, after the predetermined wear threshold is satisfied, the adapter apparatus 100 can automatically invalidate itself for further testing, thereby reducing continued use of an over-worn fixture, improving repeatability of test results, and reducing damage risk to associated connectors and reference devices.

In some embodiments, the logic circuitry 140 is configured to retrieve the cumulative usage count from the non-volatile memory 146 upon power-up, initialization, reset, or activation of the adapter apparatus 100. After a detected signal 132 corresponding to a valid test event has been identified, the logic circuitry 140 may update the cumulative usage count and store the updated cumulative usage count back into the non-volatile memory 146. In this manner, the adapter apparatus 100 can preserve life-consumption information across power interruptions, test-station shutdowns, and repeated deployment in different testing sessions.

In some implementations, retrieval of the cumulative usage count from the non-volatile memory 146 upon power-up can permit the logic circuitry 140 to immediately determine whether the adapter apparatus 100 remains valid for further use or whether a predetermined wear threshold has already been satisfied. Thus, the lockout function described above need not depend on accumulation of new test events during a current power cycle, and the adapter apparatus 100 can maintain continuity of lifetime tracking over an extended operational history.

Although FIG. 3 illustrates the adapter apparatus 100 in a generalized form, the adapter apparatus 100 may be implemented in a variety of pluggable-device testing environments. In some embodiments, the device under test comprises a storage backplane and the pluggable electronic device comprises a storage drive. In such embodiments, the electrical interconnection 130 may carry storage-interface signals between the storage backplane and the storage drive, and the detected signal 132 may be derived from a storage-related activity or status signal associated with a test event.

In one more specific storage embodiment, the first connector 110 may comprise a male connector configured to mate with the storage backplane, and the second connector 120 may comprise a female connector configured to receive a solid-state drive (SSD). In such an arrangement, the detected signal 132 may comprise a drive active LED signal or another drive-activity-related signal associated with operation of the storage path under test. The logic circuitry / CPLD 140 may monitor that drive active LED signal, apply the signal conditioning logic / debounce filter 142 to avoid multiple counts arising from rapid fluctuations during a single test operation, and determine the cumulative usage count based on filtered occurrences of the signal.

In other embodiments, the device under test may comprise a server-side Peripheral Component Interconnect Express (PCIe) receptacle, and the pluggable electronic device may comprise a PCIe add-in card. In such embodiments, the first connector 110 and the second connector 120 may be configured in accordance with the relevant PCIe form factor or interposer arrangement, while the electrical interconnection / pass-through path 130 carries PCIe-related data, control, sideband, and power signals through the adapter apparatus 100. The detected signal 132 in such embodiments may comprise, for example, a reset signal, a presence signal, a clock request signal, a link-up indication, or a link training state transition associated with a test event.

In further embodiments, the pluggable electronic device may comprise a riser card, and the first connector 110 may be configured to mate with a motherboard or an expansion slot of the device under test. In such embodiments, the adapter apparatus 100 can be used as an interposed test fixture for repeated functional testing of riser-card connectivity and associated interface behavior, while concentrating connector wear at the adapter apparatus 100 rather than at the riser card itself.

In still further embodiments, the device under test may comprise a memory expansion slot, and the pluggable electronic device may comprise a Dual In-line Memory Module (DIMM) or a Compute Express Link (CXL) memory module. In such embodiments, the adapter apparatus 100 may be configured as an intermediate interposer between the memory expansion slot and the memory module so that repeated test insertion cycles are borne by the adapter apparatus 100. The detected signal 132 in such embodiments may be selected from one or more signals indicative of successful installation, training, readiness, or operation of the memory module within the relevant interface standard.

The foregoing storage, PCIe, riser-card, and memory-module examples illustrate that the architecture of FIG. 3 is not limited to a single connector standard or protocol. Rather, the first connector 110, the second connector 120, the electrical interconnection / pass-through path 130, the detected signal 132, and the particular electrical interface-detection signal altered for invalidation may be adapted to the requirements of a given pluggable-device testing environment while preserving the same general functions of pass-through testing, cumulative usage tracking, persistent storage of usage information, and threshold-based invalidation.

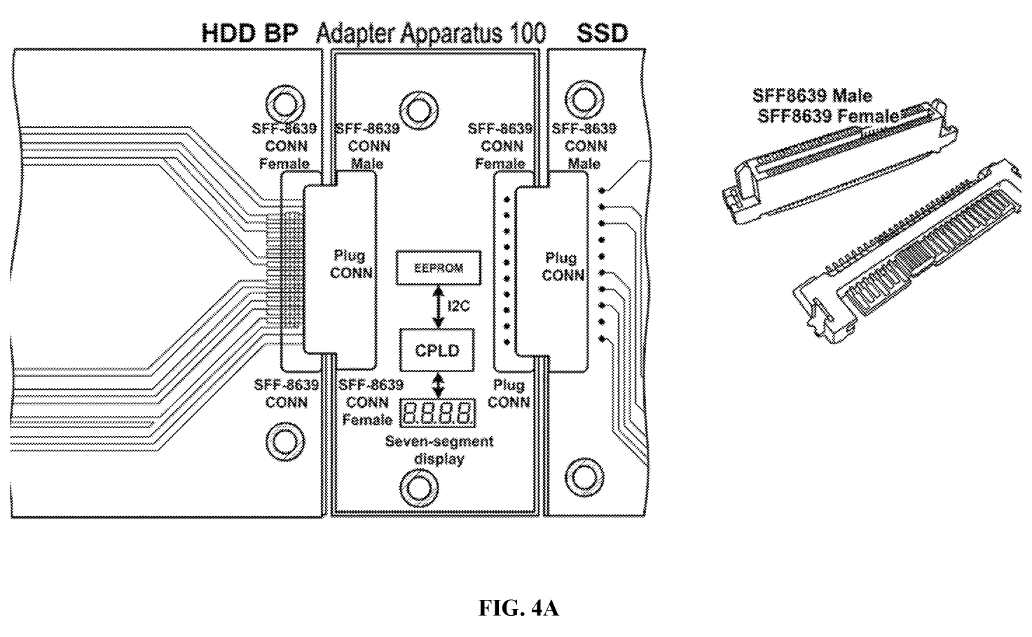

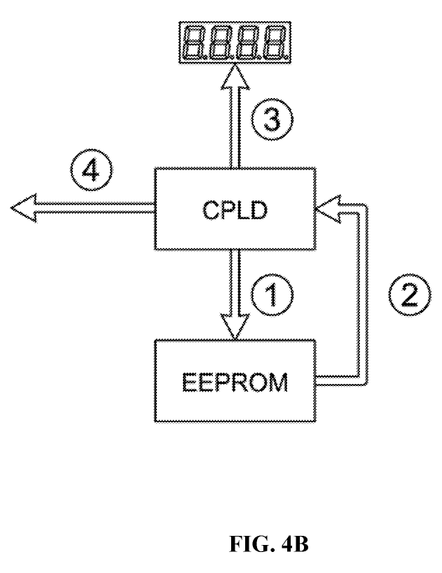

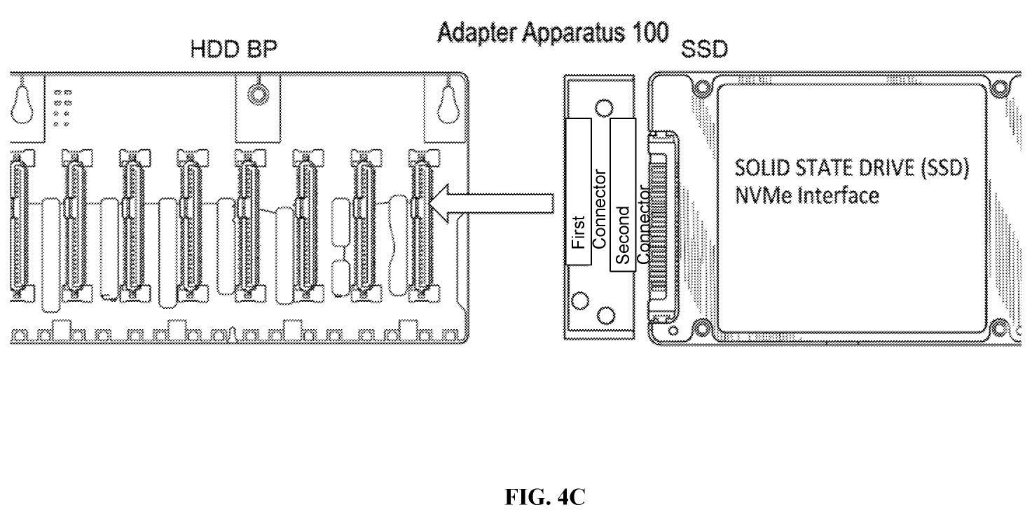

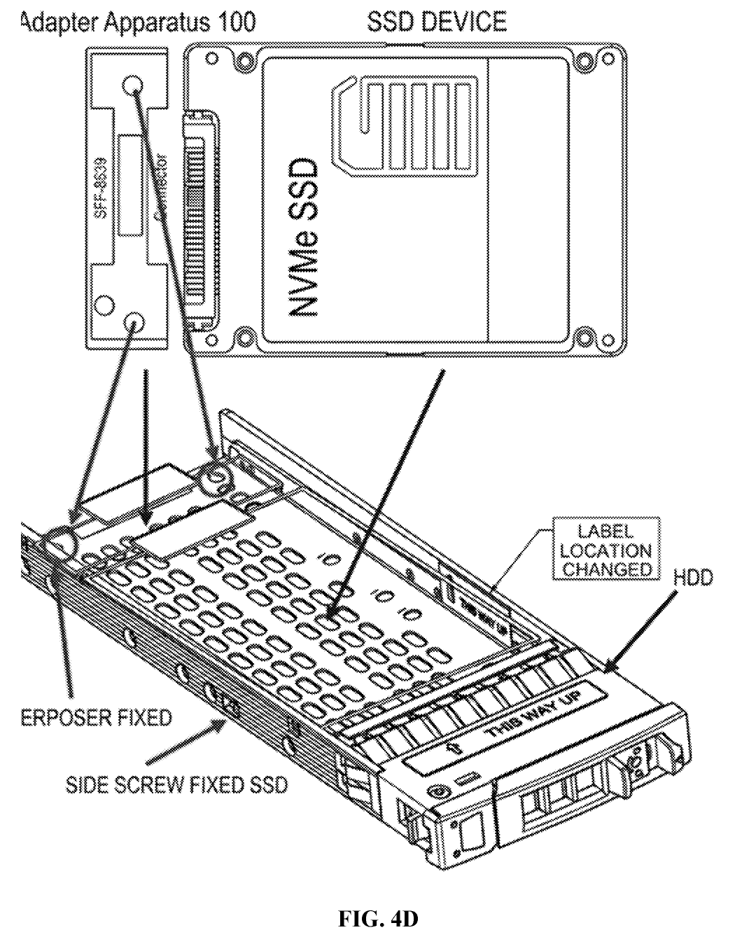

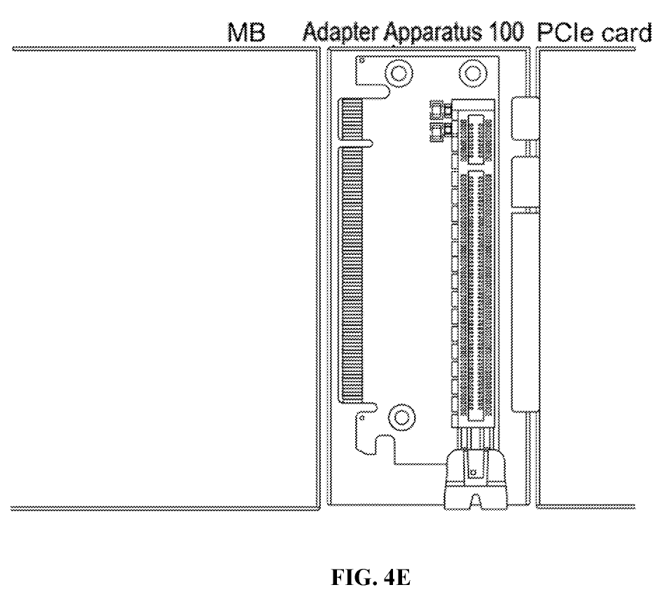

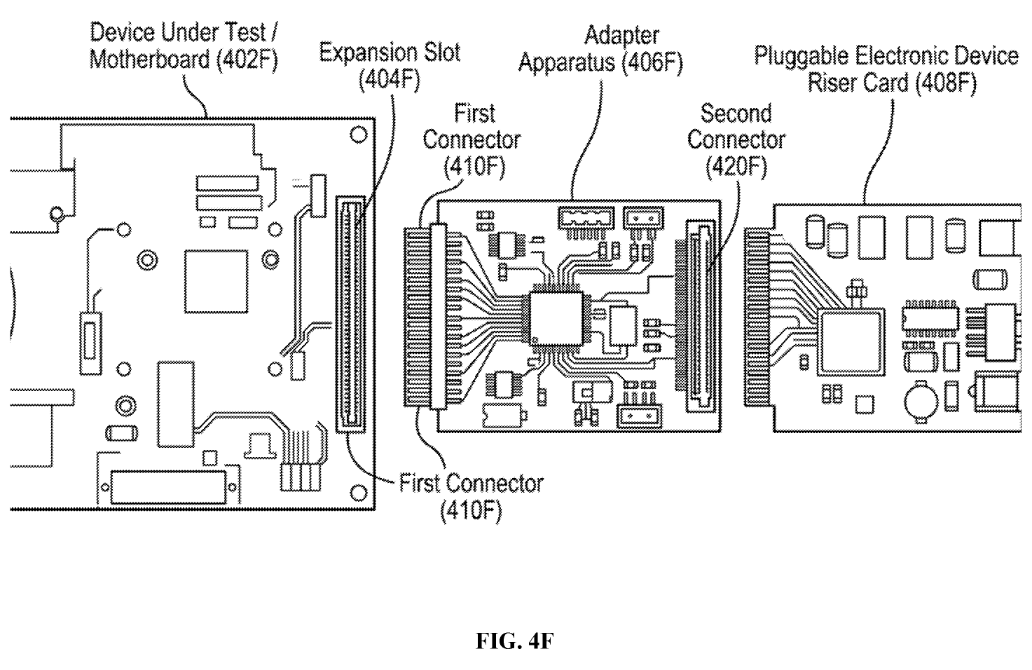

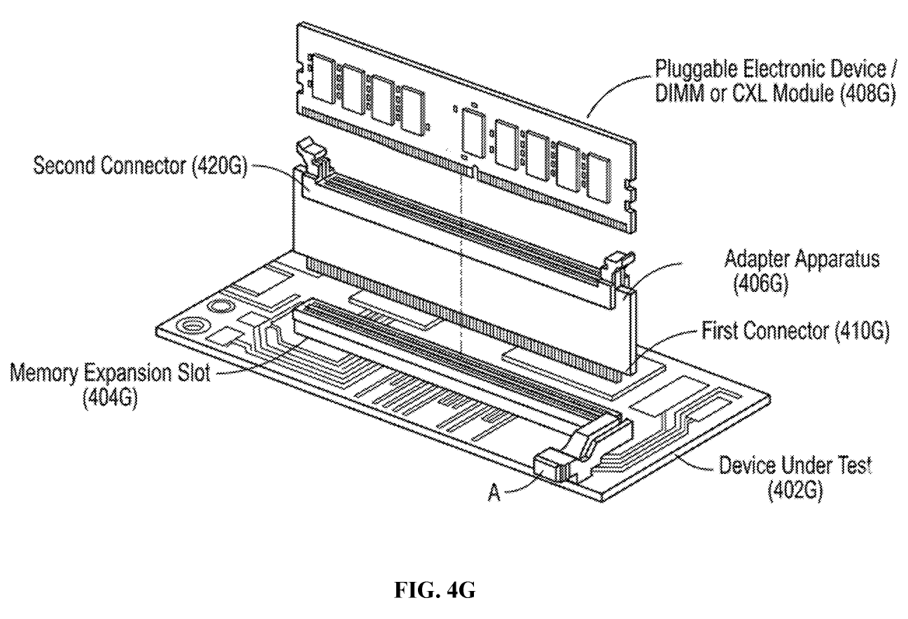

FIG. 4A is a schematic block diagram illustrating an embodiment of the adapter apparatus 100 configured for use between an HDD BACKPLANE and an SSD, in accordance with some embodiments. In the illustrated embodiment, the adapter apparatus 100 is arranged between a connector region of the HDD BACKPLANE and a connector region of the SSD such that the adapter apparatus 100 is physically and electrically interposed between the HDD BACKPLANE and the SSD during functional testing.

As shown in FIG. 4A, the HDD BACKPLANE side includes an SFF-8639 CONN/connector Female, and the SSD side includes an SFF-8639 CONN/connector Male. The adapter apparatus 100 correspondingly includes an SFF-8639 CONN Male at the side facing the HDD BACKPLANE and an SFF-8639 CONN Female at the side facing the SSD. In this manner, the adapter apparatus 100 may be removably coupled to the HDD BACKPLANE through the SFF-8639 CONN Male of the adapter apparatus 100 mating with the SFF-8639 CONN Female of the HDD BACKPLANE, while the SSD may be removably coupled to the adapter apparatus 100 through the SFF-8639 CONN Male of the SSD mating with the SFF-8639 CONN Female of the adapter apparatus 100.

In the illustrated embodiment, the SFF-8639 connector arrangement provides an example implementation of the first connector and the second connector described above with respect to the broader embodiments of FIGS. 2 and 3. More specifically, the SFF-8639 CONN Male of the adapter apparatus 100 at the HDD BACKPLANE side may correspond to the first connector 110, and the SFF-8639 CONN Female of the adapter apparatus 100 at the SSD side may correspond to the second connector 120. Likewise, the electrical routing between those connectors may define the electrical interconnection / pass-through path 130 discussed above. The specific connector format shown in FIG. 4A is provided as one non-limiting example. In other embodiments, other storage-device connector formats or other pluggable interface standards may be used.

FIG. 4A further shows that the adapter apparatus 100 may include control and storage components mounted on an intermediate board body positioned between the two connector regions. In the illustrated embodiment, the adapter apparatus 100 includes a CPLD, an EEPROM, an I2C connection between the CPLD and the EEPROM, and a seven-segment display. The CPLD may implement the logic circuitry described above, including monitoring of one or more detected signals associated with a test event, determination of a cumulative usage count, comparison of the cumulative usage count against a predetermined wear threshold, and generation of one or more outputs associated with invalidation of the adapter apparatus 100 for further testing. The EEPROM may provide non-volatile storage for the cumulative usage count, and the I2C connection may provide one example of a communication interface between the logic circuitry and the non-volatile memory. In other embodiments, a different programmable logic device, controller, memory type, or communication protocol may be used.

The seven-segment display shown in FIG. 4A may provide a local visual output associated with operation of the adapter apparatus 100. In some embodiments, the seven-segment display may present the cumulative usage count, a remaining-life indication, a threshold-reached condition, an invalidation warning, or another status indication. In some implementations, the CPLD may control the seven-segment display so that the display changes state when the predetermined wear threshold has been satisfied, thereby providing a local visible indication that the adapter apparatus 100 should no longer be used for further testing.

In use, the adapter apparatus 100 of FIG. 4A may be inserted between the HDD BACKPLANE and a reference SSD previously verified to be operational. During a test sequence, the adapter apparatus 100 permits electrical communication between the HDD BACKPLANE and the SSD through the pass-through connection while shifting the repeated mechanical insertion and removal cycles away from the SSD-side connector itself and onto the adapter apparatus 100. As a result, repeated production-line or verification-station testing can be performed using the adapter apparatus 100 as a sacrificial wear component.

In some embodiments, the adapter apparatus 100 may monitor a signal associated with a test event occurring over the HDD BACKPLANE-to-SSD path and may update a cumulative usage count based on that signal. When the cumulative usage count satisfies the predetermined wear threshold, the adapter apparatus 100 may invalidate itself for further testing by altering at least one electrical interface-detection signal, as described above with respect to FIG. 3. For example, the CPLD may alter a presence or readiness condition associated with the HDD BACKPLANE-side connector, the SSD-side connector, or both, depending on the particular implementation.

Accordingly, FIG. 4A illustrates one specific storage-interface embodiment of the broader test adapter apparatus disclosed herein. In this embodiment, the use of SFF-8639 connector structures, a CPLD, an EEPROM, an I2C connection, and a seven-segment display provides a practical implementation for repeated testing of an HDD BACKPLANE with a reference SSD. However, the particular connector names and component choices shown in FIG. 4A are provided as examples, and other connector standards, logic devices, memory devices, display devices, and signaling arrangements may be used in other embodiments while still implementing the same underlying functions.

FIG. 4B is a logical state diagram illustrating example data flow and operation among a Complex Programmable Logic Device (CPLD), an EEPROM, and a display of the test adapter apparatus during a test cycle, in accordance with some embodiments.

As shown in FIG. 4B, the CPLD may monitor a signal associated with a test event, such as an HDD active LED signal, and may determine a cumulative usage count of the test adapter apparatus based on the detected signal. In the illustrated example, the CPLD writes the insertion/removal count to the EEPROM via an I2C interface, as represented by step 1.

The EEPROM may return the stored count information to the CPLD, for example in response to a read operation, initialization sequence, or verification operation, as represented by step 2. In some embodiments, this read-back operation enables the CPLD to retrieve a previously stored cumulative usage count upon power-up or during subsequent operation so that the count is retained across multiple testing sessions.

As represented by step 3, the CPLD may output the cumulative usage count to a display, such as a seven-segment display, thereby providing a local visual indication of fixture usage. In some embodiments, the displayed value may correspond to the current cumulative usage count, a remaining-life value, or another usage-related status.

As represented by step 4, the CPLD may compare the cumulative usage count with a preset threshold. When the cumulative usage count reaches or exceeds the threshold, the CPLD may actively alter an interface-detection signal, such as a present signal, through associated logic circuitry so as to invalidate the test adapter apparatus for further testing. In some embodiments, this operation causes the fixture card to be treated as failed, absent, or unready by the relevant test environment.

Although FIG. 4B illustrates an example sequence involving a CPLD, an EEPROM, an I2C interface, and a seven-segment display, other implementations may use a different programmable logic device, a different type of non-volatile memory, a different communication protocol, or a different visual output device while performing the same general functions of usage tracking, persistent count storage, local indication, and threshold-based invalidation.

FIG. 4C is a plan view illustrating the physical form factor of the adapter apparatus 100 interposed between an HDD BACKPLANE and an SSD, in accordance with some embodiments.

As shown in FIG. 4C, the adapter apparatus 100 is physically positioned between the HDD BACKPLANE and the SSD such that a first connector of the adapter apparatus 100 faces the HDD BACKPLANE and a second connector of the adapter apparatus 100 faces the SSD. In this arrangement, the adapter apparatus 100 functions as an intermediate fixture that is received between the HDD BACKPLANE-side interface and the SSD-side interface while maintaining the electrical connection therebetween.

In some embodiments, the adapter apparatus 100 has a compact board form factor sized to fit within the available connection space between the HDD BACKPLANE and the SSD without materially changing the basic insertion relationship of the two components. The first connector and the second connector may be arranged in an opposed configuration so that the adapter apparatus 100 can be inserted inline along the mating direction between the HDD BACKPLANE and the SSD.

As further illustrated in FIG. 4C, the adapter apparatus 100 may be configured such that repeated insertion and removal during testing occurs at the adapter apparatus 100 rather than directly at the connector of the SSD. In this manner, the adapter apparatus 100 can serve as a sacrificial wear component while preserving the ability of the HDD BACKPLANE and the SSD to communicate through the interposed connection.

FIG. 4D is an exploded perspective view illustrating an example mechanical assembly in which the adapter apparatus 100 mates an SSD device to a storage carrier tray, in accordance with some embodiments.

As shown in FIG. 4D, the adapter apparatus 100 may be mechanically coupled to the SSD device at the connector side of the SSD device so that the adapter apparatus 100 extends the connection interface of the SSD device toward the carrier tray. In some embodiments, the adapter apparatus 100 is fixed relative to the SSD device, for example by one or more fasteners or other mounting features, such that the adapter apparatus 100 and the SSD device may be handled together during insertion into and removal from the carrier tray.

In the illustrated arrangement, the SSD device and the adapter apparatus 100 are positioned for installation into the carrier tray, and the carrier tray in turn may be inserted into a corresponding slot of an HDD BACKPLANE or related storage system. This arrangement can facilitate repeated testing while mechanically supporting the adapter apparatus 100 and the SSD device in a consistent alignment during mating operations.

In some embodiments, the carrier tray, side fasteners, interposer mounting, and label placement shown in FIG. 4D represent one example mechanical implementation. Other mounting structures, retention features, fastening arrangements, or tray formats may be used while still positioning the adapter apparatus 100 between the SSD device and a corresponding storage-side interface so that the adapter apparatus 100 functions as a sacrificial wear component during repeated testing.

FIG. 4E is a schematic plan view illustrating an embodiment of the adapter apparatus 100 configured for testing a Peripheral Component Interconnect Express (PCIe) card with a motherboard (MB), in accordance with some embodiments.

As shown in FIG. 4E, the adapter apparatus 100 is positioned between the MB and the PCIe card such that the adapter apparatus 100 is mechanically and electrically interposed between a motherboard-side PCIe receptacle and a connector portion of the PCIe card. In this embodiment, the adapter apparatus 100 provides an intermediate connection structure through which PCIe-related signals may pass between the MB and the PCIe card during testing, while repeated insertion and removal cycles are borne by the adapter apparatus 100 rather than directly by the PCIe card.

FIG. 4E illustrates another type of repeated functional testing environment in which the pluggable electronic device is not a storage drive, but instead is a PCIe card used to verify operation of a motherboard-side PCIe interface. In some embodiments, the PCIe card may be a reference device previously verified to be operational and may be used across multiple motherboards or multiple PCIe receptacles during manufacturing, qualification, repair, or diagnostic testing.

In one example testing procedure, the adapter apparatus 100 may first be coupled to the PCIe card, and the resulting assembly may then be inserted into a corresponding PCIe receptacle of the MB. After electrical connection is established through the adapter apparatus 100, a host system may power the PCIe interface, detect the PCIe card, and perform one or more verification operations directed to the motherboard-side PCIe path under test. By way of example, the verification operations may include determining whether the PCIe card is enumerated, whether one or more lanes train successfully, whether link-up is achieved, whether reset or clock-related signaling behaves as expected, whether configuration or status transactions complete successfully, and whether data communication through the PCIe path occurs correctly.

In some embodiments, a signal associated with a test event in the PCIe environment may comprise a reset signal, a presence signal, a clock request signal, a link-up indication, or a link training state transition. The adapter apparatus 100 may monitor such a signal, determine a cumulative usage count based on the monitored signal, and invalidate itself for further testing when a predetermined wear threshold has been satisfied, as described above with respect to the generalized embodiments.

Accordingly, FIG. 4E demonstrates that the adapter apparatus 100 is not limited to HDD backplane and SSD testing, and may also be used in a PCIe-card testing environment in which repeated mating cycles would otherwise be applied directly to the motherboard-side connector and/or the PCIe card connector. By interposing the adapter apparatus 100 between the MB and the PCIe card, wear can be concentrated at the adapter apparatus 100 while preserving the use of a known operational PCIe card as a reference device for repeated verification.

FIG. 4F is a schematic plan view illustrating another embodiment of a test adapter apparatus (406F) configured for testing a riser card with an expansion slot (404F) of a device under test / motherboard (402F), in accordance with some embodiments.

As shown in FIG. 4F, the test adapter apparatus (406F) is positioned between the expansion slot (404F) of the device under test / motherboard (402F) and a pluggable electronic device / riser card (408F). In the illustrated embodiment, the test adapter apparatus (406F) includes a first connector (410F) configured to mate with the expansion slot (404F), and a second connector (420F) configured to mate with a corresponding connector of the pluggable electronic device / riser card (408F). In this manner, the test adapter apparatus (406F) is mechanically and electrically interposed between the device under test / motherboard (402F) and the pluggable electronic device / riser card (408F).

FIG. 4F illustrates another type of repeated functional testing environment in which the pluggable electronic device comprises a riser card. In some embodiments, a riser card previously verified to be operational may be used as a reference device for testing multiple motherboards, multiple expansion slots, or repeated test cycles associated with a given system. By positioning the test adapter apparatus (406F) between the expansion slot (404F) and the pluggable electronic device / riser card (408F), repeated insertion and removal cycles can be concentrated at the first connector (410F) and the second connector (420F) of the test adapter apparatus (406F) rather than directly at the riser card connector itself.

In one example testing procedure, the test adapter apparatus (406F) may first be coupled to the pluggable electronic device / riser card (408F), and the resulting assembly may then be inserted into the expansion slot (404F) of the device under test / motherboard (402F). After connection is established through the test adapter apparatus (406F), the host system may perform one or more verification operations directed to the expansion-slot path under test. By way of example, the verification operations may include determining whether the riser card is detected, whether expected power or sideband signaling is present, whether signals are routed correctly through the slot interface, whether downstream interfaces of the riser card are made available as expected, and whether communication through the riser-card path is established correctly.

In some embodiments, the test adapter apparatus (406F) may monitor a signal associated with a test event occurring in the riser-card environment, determine a cumulative usage count based on the monitored signal, and compare the cumulative usage count to a predetermined wear threshold. When the predetermined wear threshold is satisfied, the test adapter apparatus (406F) may invalidate itself for further testing by altering at least one electrical interface-detection signal associated with the first connector (410F), the second connector (420F), or both, in the manner described above with respect to other embodiments.

Accordingly, FIG. 4F further illustrates that the disclosed test adapter architecture may be applied to testing environments other than storage-drive testing and PCIe add-in card testing. In the riser-card embodiment, the test adapter apparatus (406F) can protect the connector of a reference riser card and/or the corresponding slot-side connection from repeated mating wear while preserving the ability to use the riser card as a known operational endpoint for repeated functional verification.

FIG. 4G is a perspective view illustrating yet another embodiment of a test adapter apparatus (406G) configured for testing a Dual In-line Memory Module (DIMM) or a Compute Express Link (CXL) module with a memory expansion slot (404G), in accordance with some embodiments.

As shown in FIG. 4G, the test adapter apparatus (406G) is positioned between the memory expansion slot (404G) of the device under test (402G) and a pluggable electronic device / DIMM or CXL module (408G). In the illustrated embodiment, the test adapter apparatus (406G) includes a first connector (410G) configured to mate with the memory expansion slot (404G), and a second connector (420G) configured to receive the pluggable electronic device / DIMM or CXL module (408G). In this manner, the test adapter apparatus (406G) is mechanically and electrically interposed between the device under test (402G) and the pluggable electronic device / DIMM or CXL module (408G).

FIG. 4G illustrates another type of repeated functional testing environment in which the pluggable electronic device comprises a memory module rather than a storage device, a PCIe card, or a riser card. In some embodiments, a DIMM or CXL module previously verified to be operational may be used as a reference device for testing multiple devices under test (402G), multiple memory expansion slots (404G), or repeated memory-interface verification cycles associated with a given system. By positioning the test adapter apparatus (406G) between the memory expansion slot (404G) and the pluggable electronic device / DIMM or CXL module (408G), repeated insertion and removal cycles can be concentrated at the first connector (410G) and the second connector (420G) of the test adapter apparatus (406G) rather than directly at the connector region of the memory module.

In one example testing procedure, the test adapter apparatus (406G) may first be coupled to the pluggable electronic device / DIMM or CXL module (408G), and the resulting assembly may then be inserted into the memory expansion slot (404G) of the device under test (402G). After connection is established through the test adapter apparatus (406G), the host system may perform one or more verification operations directed to the memory-slot path under test. By way of example, the verification operations may include determining whether the memory module is detected, whether initialization or training completes successfully, whether expected control or status signaling is present, whether data transactions through the memory path occur correctly, and whether the module is accessible for subsequent read, write, or diagnostic operations.

In some embodiments, the test adapter apparatus (406G) may monitor a signal associated with a test event occurring in the memory-module environment, determine a cumulative usage count based on the monitored signal, and compare the cumulative usage count to a predetermined wear threshold. When the predetermined wear threshold is satisfied, the test adapter apparatus (406G) may invalidate itself for further testing by altering at least one electrical interface-detection signal associated with the first connector (410G), the second connector (420G), or both, in the manner described above with respect to other embodiments.

Accordingly, FIG. 4G further illustrates that the disclosed test adapter architecture may be adapted to memory-interface testing environments in addition to storage and expansion-card testing environments. In the DIMM or CXL embodiment, the test adapter apparatus (406G) can protect a reference memory module and/or the corresponding slot-side connection from repeated mating wear while preserving the ability to use the memory module as a known operational endpoint for repeated functional verification.

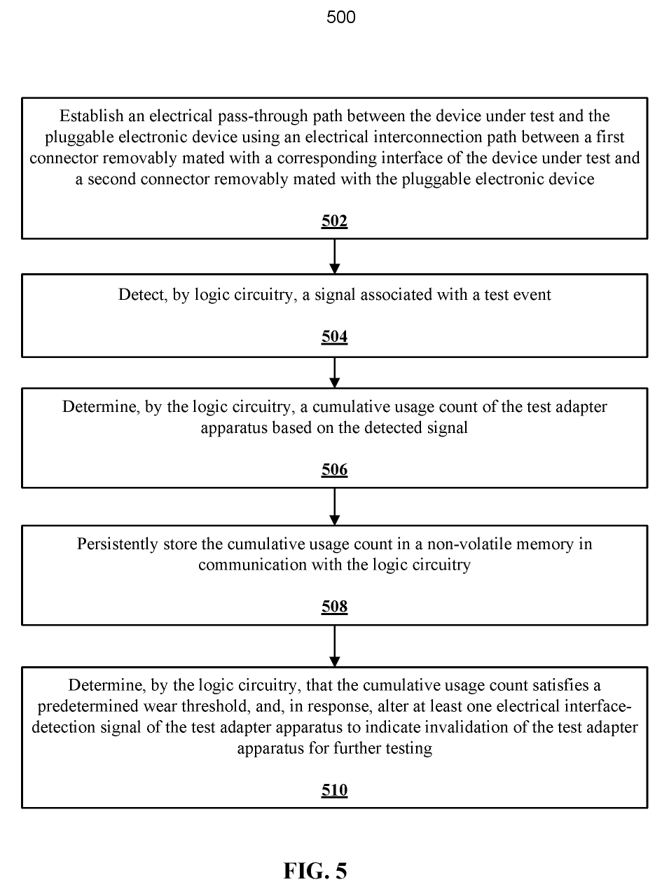

FIG. 5 is a flowchart of an example process 500. In some implementations, one or more process blocks of FIG. 5 may be performed by a device.

As shown in FIG. 5, process 500 may include establishing an electrical pass-through path between the device under test and the pluggable electronic device using an electrical interconnection path between a first connector removably mated with a corresponding interface of the device under test and a second connector removably mated with the pluggable electronic device (block 502). For example, the device may establish an electrical pass-through path between the device under test and the pluggable electronic device using an electrical interconnection path between a first connector removably mated with a corresponding interface of the device under test and a second connector removably mated with the pluggable electronic device, as described above. As also shown in FIG. 5, process 500 may include detecting, by logic circuitry, a signal associated with a test event (block 504). For example, the device may detect, by logic circuitry, a signal associated with a test event, as described above. As further shown in FIG. 5, process 500 may include determining, by the logic circuitry, a cumulative usage count of the test adapter apparatus based on the detected signal (block 506). For example, the device may determine, by the logic circuitry, a cumulative usage count of the test adapter apparatus based on the detected signal, as described above. As also shown in FIG. 5, process 500 may include persistently storing the cumulative usage count in a non-volatile memory in communication with the logic circuitry (block 508). For example, the device may persistently store the cumulative usage count in a non-volatile memory in communication with the logic circuitry, as described above. As further shown in FIG. 5, process 500 may include determining, by the logic circuitry, that the cumulative usage count satisfies a predetermined wear threshold and, in response, altering at least one electrical interface-detection signal of the test adapter apparatus to indicate invalidation of the test adapter apparatus for further testing (block 510). For example, the device may determine, by the logic circuitry, that the cumulative usage count satisfies a predetermined wear threshold and, in response, alter at least one electrical interface-detection signal of the test adapter apparatus to indicate invalidation of the test adapter apparatus for further testing, as described above.

Process 500 may include additional implementations, such as any single implementation or any combination of implementations described below and/or in connection with one or more other processes described elsewhere herein. In a first implementation, altering the at least one electrical interface-detection signal may include pulling down, interrupting, or forcing a state of a presence pin or a readiness pin of the first connector to simulate an absent or unready condition to the device under test or the pluggable electronic device.

In a second implementation, alone or in combination with the first implementation, process 500 further includes applying, by signal conditioning logic of the logic circuitry, a debounce filter or a defined time window to the detected signal, such that a plurality of signal fluctuations occurring during the test event are interpreted as a single valid cycle for the cumulative usage count.

Although FIG. 5 shows example blocks of process 500, in some implementations, process 500 may include additional blocks, fewer blocks, different blocks, or differently arranged blocks than those depicted in FIG. 5. Additionally, or alternatively, two or more of the blocks of process 500 may be performed in parallel.

The performance of certain of the operations may be distributed among the processors, not only residing within a single machine, but deployed across a number of machines. In some example embodiments, the processors or processor-implemented engines may be located in a single geographic location (e.g., within a home environment, an office environment, or a server farm). In other example embodiments, the processors or processor-implemented engines may be distributed across a number of geographic locations.

Each process, method, and algorithm described in the preceding sections may be embodied in, and fully or partially automated by, code modules executed by one or more computer systems or computer processors comprising computer hardware. The processes and algorithms may be implemented partially or wholly in application-specific circuitry.

When the functions disclosed herein are implemented in the form of software functional units and sold or used as independent products, they can be stored in a processor executable non-volatile computer readable storage medium. Particular technical solutions disclosed herein (in whole or in part) or aspects that contribute to current technologies may be embodied in the form of a software product. The software product may be stored in a storage medium, comprising a number of instructions to cause a computing device (which may be a personal computer, a server, a network device, and the like) to execute all or some steps of the methods of the embodiments of the present application. The storage medium may comprise a flash drive, a portable hard drive, ROM, RAM, a magnetic disk, an optical disc, another medium operable to store program code, or any combination thereof.

Particular embodiments further provide a system comprising a processor and a non-transitory computer-readable storage medium storing instructions executable by the processor to cause the system to perform operations corresponding to steps in any method of the embodiments disclosed above. Particular embodiments further provide a non-transitory computer-readable storage medium configured with instructions executable by one or more processors to cause the one or more processors to perform operations corresponding to steps in any method of the embodiments disclosed above.

Embodiments disclosed herein may be implemented through a cloud platform, a server or a server group (hereinafter collectively the “service system”) that interacts with a client. The client may be a terminal device, or a client registered by a user at a platform, wherein the terminal device may be a mobile terminal, a personal computer (PC), and any device that may be installed with a platform application program.

The various features and processes described above may be used independently of one another or may be combined in various ways. All possible combinations and sub-combinations are intended to fall within the scope of this disclosure. In addition, certain method or process blocks may be omitted in some implementations. The methods and processes described herein are also not limited to any particular sequence, and the blocks or states relating thereto can be performed in other sequences that are appropriate. For example, described blocks or states may be performed in an order other than that specifically disclosed, or multiple blocks or states may be combined in a single block or state. The example blocks or states may be performed in serial, in parallel, or in some other manner. Blocks or states may be added to or removed from the disclosed example embodiments. The exemplary systems and components described herein may be configured differently than described. For example, elements may be added to, removed from, or rearranged compared to the disclosed example embodiments.

The various operations of exemplary methods described herein may be performed, at least partially, by an algorithm. The algorithm may be comprised in program codes or instructions stored in a memory (e.g., a non-transitory computer-readable storage medium described above). Such an algorithm may comprise a machine learning algorithm. In some embodiments, a machine learning algorithm may not explicitly program computers to perform a function but can learn from training data to make a prediction model that performs the function.

The various operations of exemplary methods described herein may be performed, at least partially, by one or more processors that are temporarily configured (e.g., by software) or permanently configured to perform the relevant operations. Whether temporarily or permanently configured, such processors may constitute processor-implemented engines that operate to perform one or more operations or functions described herein.

Similarly, the methods described herein may be at least partially processor-implemented, with a particular processor or processors being an example of hardware. For example, at least some of the operations of a method may be performed by one or more processors or processor-implemented engines. Moreover, the one or more processors may also operate to support performance of the relevant operations in a “cloud computing” environment or as a “software as a service” (SaaS). For example, at least some of the operations may be performed by a group of computers (as examples of machines including processors), with these operations being accessible via a network (e.g., the Internet) and via one or more appropriate interfaces (e.g., an Application Program Interface (API)).

The performance of certain of the operations may be distributed among the processors, not only residing within a single machine, but deployed across a number of machines. In some example embodiments, the processors or processor-implemented engines may be located in a single geographic location (e.g., within a home environment, an office environment, or a server farm). In other example embodiments, the processors or processor-implemented engines may be distributed across a number of geographic locations.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

Although an overview of the subject matter has been described with reference to specific example embodiments, various modifications and changes may be made to these embodiments without departing from the broader scope of embodiments of the present disclosure. Such embodiments of the subject matter may be referred to herein, individually or collectively, by the term “invention” merely for convenience and without intending to voluntarily limit the scope of this application to any single disclosure or concept if more than one is, in fact, disclosed.

The embodiments illustrated herein are described in sufficient detail to enable those skilled in the art to practice the teachings disclosed. Other embodiments may be used and derived therefrom, such that structural and logical substitutions and changes may be made without departing from the scope of this disclosure. The Detailed Description, therefore, is not to be taken in a limiting sense, and the scope of various embodiments is defined only by the appended claims, along with the full range of equivalents to which such claims are entitled.

Any process descriptions, elements, or blocks in the flow diagrams described herein and/or depicted in the attached figures should be understood as potentially representing modules, segments, or portions of code which include one or more executable instructions for implementing specific logical functions or steps in the process. Alternate implementations are included within the scope of the embodiments described herein in which elements or functions may be deleted, executed out of order from that shown or discussed, including substantially concurrently or in reverse order, depending on the functionality involved, as would be understood by those skilled in the art.

As used herein, “or” is inclusive and not exclusive, unless expressly indicated otherwise or indicated otherwise by context. Therefore, herein, “A, B, or C” means “A, B, C, A and B, A and C, B and C, or A, B, and C,” unless expressly indicated otherwise or indicated otherwise by context. Moreover, “and” is both joint and several, unless expressly indicated otherwise or indicated otherwise by context. Therefore, herein, “A and B” means “A and B, jointly or severally,” unless expressly indicated otherwise or indicated otherwise by context. Moreover, plural instances may be provided for resources, operations, or structures described herein as a single instance. Additionally, boundaries between various resources, operations, engines, and data stores are somewhat arbitrary, and particular operations are illustrated in a context of specific illustrative configurations. Other allocations of functionality are envisioned and may fall within a scope of various embodiments of the present disclosure. In general, structures and functionality presented as separate resources in the example configurations may be implemented as a combined structure or resource. Similarly, structures and functionality presented as a single resource may be implemented as separate resources. These and other variations, modifications, additions, and improvements fall within a scope of embodiments of the present disclosure as represented by the appended claims. The specification and drawings are, accordingly, to be regarded in an illustrative rather than a restrictive sense.

The term “include” or “comprise” is used to indicate the existence of the subsequently declared features, but it does not exclude the addition of other features. Conditional language, such as, among others, “can,” “could,” “might,” or “may,” unless specifically stated otherwise, or otherwise understood within the context as used, is generally intended to convey that certain embodiments include, while other embodiments do not include, certain features, elements and/or steps. Thus, such conditional language is not generally intended to imply that features, elements and/or steps are in any way required for one or more embodiments or that one or more embodiments necessarily include logic for deciding, with or without user input or prompting, whether these features, elements and/or steps are included or are to be performed in any particular embodiment.

What is claimed is:

1. A test adapter apparatus for use in repeated functional testing of a pluggable electronic device with respect to a device under test, the test adapter apparatus comprising:
a first connector configured to removably mate with a corresponding interface of the device under test;
a second connector configured to removably mate with the pluggable electronic device;
an electrical interconnection path between the first connector and the second connector to establish an electrical pass-through path between the device under test and the pluggable electronic device;
logic circuitry configured to detect a signal associated with a test event and determine a cumulative usage count of the test adapter apparatus based on the detected signal;
a non-volatile memory in communication with the logic circuitry, the non-volatile memory configured to store the cumulative usage count; and
the logic circuitry further configured to determine that the cumulative usage count satisfies a predetermined wear threshold, and, in response, alter at least one electrical interface-detection signal of the test adapter apparatus to indicate invalidation of the test adapter apparatus for further testing.

2. The test adapter apparatus of claim 1, wherein altering the at least one electrical interface-detection signal comprises:
pulling down, interrupting, or forcing a state of a presence pin or a readiness pin of the first connector to simulate an absent or unready condition of the device under test.

3. The test adapter apparatus of claim 1, wherein altering the at least one electrical interface-detection signal comprises:
pulling down, interrupting, or forcing a state of a presence pin or a readiness pin of the second connector to simulate an absent or unready condition of the pluggable electronic device.

4. The test adapter apparatus of claim 1, wherein the logic circuitry is further configured to:
provide, via a display or an LED, a visual warning indicating that the predetermined wear threshold has been satisfied.

5. The test adapter apparatus of claim 1, wherein the logic circuitry comprises signal conditioning logic configured to:
apply a debounce filter or a defined time window to the detected signal, such that a plurality of signal fluctuations occurring during the test event are interpreted as a single valid cycle for the cumulative usage count.

6. The test adapter apparatus of claim 1, wherein the detected signal associated with the test event comprises:
an active signal,
a reset signal,
a presence signal,
a clock request signal,
a link-up indication, or
a link training state transition.

7. The test adapter apparatus of claim 1, wherein the logic circuitry comprises a Complex Programmable Logic Device (CPLD), and
wherein the non-volatile memory is in communication with the CPLD.

8. The test adapter apparatus of claim 1, wherein the non-volatile memory communicates with the logic circuitry over an I2C interface.

9. The test adapter apparatus of claim 1, wherein the logic circuitry is configured to:
retrieve the cumulative usage count from the non-volatile memory upon power-up, and
store an updated cumulative usage count in the non-volatile memory after detection of the test event.

10. The test adapter apparatus of claim 1, wherein the device under test comprises a storage backplane, and the pluggable electronic device comprises a storage drive.

11. The test adapter apparatus of claim 10, wherein the first connector comprises a male connector configured to mate with the storage backplane,
the second connector comprises a female connector configured to receive a solid-state drive (SSD), and
the signal associated with the test event comprises a drive active LED signal.

12. The test adapter apparatus of claim 1, wherein the device under test comprises a server-side Peripheral Component Interconnect Express (PCIe) receptacle, and
the pluggable electronic device comprises a PCIe add-in card.

13. The test adapter apparatus of claim 1, wherein the pluggable electronic device comprises a riser card, and
the first connector is configured to mate with a motherboard or an expansion slot of the device under test.

14. The test adapter apparatus of claim 1, wherein the device under test comprises a memory expansion slot, and
the pluggable electronic device comprises a Dual In-line Memory Module (DIMM) or a Compute Express Link (CXL) memory module.

15. The test adapter apparatus of claim 1, wherein the pluggable electronic device comprises a reference device previously verified to be operational, and
wherein the test adapter apparatus is configured as a sacrificial wear component to protect a connector of the reference device from mechanical wear during repeated mating cycles with successive devices under test.

16. A method for use in repeated functional testing of a pluggable electronic device with respect to a device under test using a test adapter apparatus, the method comprising:
establishing an electrical pass-through path between the device under test and the pluggable electronic device using an electrical interconnection path between a first connector removably mated with a corresponding interface of the device under test and a second connector removably mated with the pluggable electronic device;
detecting, by logic circuitry, a signal associated with a test event;
determining, by the logic circuitry, a cumulative usage count of the test adapter apparatus based on the detected signal;
persistently storing the cumulative usage count in a non-volatile memory in communication with the logic circuitry; and
determining, by the logic circuitry, that the cumulative usage count satisfies a predetermined wear threshold, and, in response, altering at least one electrical interface-detection signal of the test adapter apparatus to indicate invalidation of the test adapter apparatus for further testing.

17. The method of claim 16, wherein altering the at least one electrical interface-detection signal comprises:
pulling down, interrupting, or forcing a state of a presence pin or a readiness pin of the first connector to simulate an absent or unready condition to the device under test or the pluggable electronic device.

18. The method of claim 16, further comprising:
applying, by signal conditioning logic of the logic circuitry, a debounce filter or a defined time window to the detected signal, such that a plurality of signal fluctuations occurring during the test event are interpreted as a single valid cycle for the cumulative usage count.

19. A test system for use in repeated functional testing, the test system comprising:
a device under test having an interface;
a pluggable electronic device; and
a test adapter apparatus comprising:
a first connector removably mated with the interface of the device under test;
a second connector removably mated with the pluggable electronic device;
an electrical interconnection path between the first connector and the second connector to establish an electrical pass-through path between the device under test and the pluggable electronic device;
logic circuitry configured to detect a signal associated with a test event and determine a cumulative usage count of the test adapter apparatus based on the detected signal;
a non-volatile memory in communication with the logic circuitry, the non-volatile memory configured to persistently store the cumulative usage count; and
the logic circuitry further configured to determine that the cumulative usage count satisfies a predetermined wear threshold, and, in response, alter at least one electrical interface-detection signal of the test adapter apparatus to indicate invalidation of the test adapter apparatus for further testing.

20. The test system of claim 19, wherein altering the at least one electrical interface-detection signal comprises:
pulling down, interrupting, or forcing a state of a presence pin or a readiness pin of the first connector to simulate an absent or unready condition to the device under test or the pluggable electronic device.
